(19) United States
(12) Patent Application Publication
(10) Pub. No.: US 2023/0166141 A1
(43) Pub. Date: Jun. 1, 2023

(54) FLAMEPROOF ELECTRONIC DEVICE

(71) Applicant: DELTA ELECTRONICS, INC., Taoyuan City (TW)

(72) Inventors: Jiun-Jie HUANG, Taoyuan City (TW); Chin LIEN, Taoyuan City (TW); Yu-Chi JEN, Taoyuan City (TW); Chih-Chiang CHAN, Taoyuan City (TW)

(21) Appl. No.: 17/975,494

(22) Filed: Oct. 27, 2022

Related U.S. Application Data
(60) Provisional application No. 63/283,396, filed on Nov. 26, 2021.

(30) Foreign Application Priority Data
Apr. 1, 2022 (CN) 202210348546.0

(51) Int. Cl. A62C 3/16; H01M 50/383

(52) U.S. Cl. CPC A62C 3/16; H01M 50/383

(57) ABSTRACT

This disclosure is directed to a flameproof electronic device having a housing, an electronic assembly, and a thermal-expandable structure. The housing has a pair of vents. The electronic assembly is accommodated in the housing, at least a part of the electronic assembly is spaced from the housing to enclose a flow channel between the electronic component and an internal surface of the housing, and the flow channel communicates with the vent. The thermal-expandable structure covers the internal surface of the housing or an external surface of the electronic assembly. The heat-expandable structure expands to block the flow channel when being heated to greater than or equal to a predetermined temperature.

### CROSS-REFERENCE TO RELATED APPLICATION

This patent application claims the benefit of U.S. Provisional Patent Application No. 63/283,396, filed Nov. 26, 2021, which is incorporated by reference herein.

### BACKGROUND OF THE DISCLOSURE

### Technical Field

This disclosure is directed to an electronic device, and in particular to a flameproof electronic device.

### Description of Related Art

A related-art server rack is provided with a battery energy storage system (BESS) therein, and the battery energy storage system is used as a data center backup battery unit (BBU). The data center backup battery unit has a battery pack and a battery management system, and the data center backup battery unit therefore has electronic components generating heat and has a requirement of heat dissipation. Therefore, a module housing, a chassis, a rack, or a cabinet is provided with a fan therein and vents thereon. In general, the data center backup battery unit (BBU) is configured as a module which can be inserted into the rack, and the vents are generally disposed on a front side or a rear side of the module housing of the data center backup battery unit. High temperature combustible gases with flame are generated when a thermal runaway situation occurs at cells in the battery energy storage system, and the high temperature gases and the flame run out through the vents at the front side or the rear side of the data center backup battery unit. The escaping flame increases a risk of igniting a system and a computer room outside. According to safety requirements of the battery energy storage system, flame running out of the module should be prevented when a lithium battery cell is under the thermal runaway situation.

In view of the above drawbacks, the inventor proposes this disclosure based on his expert knowledge and elaborate researches in order to solve the problems of related art.

### SUMMARY OF THE DISCLOSURE

This disclosure is directed to an electronic device, and in particular to a flameproof electronic device.

This disclosure is directed to a flameproof electronic device having a housing, an electronic assembly, and a thermal-expandable structure. The housing is provided with a pair of vents. The electronic assembly is accommodated in the housing. At least a portion of the electronic assembly is separated from the housing and a flow channel is enclosed by the electronic assembly and an internal surface of the housing, and the flow channel is extended between the pair of vents. The thermal-expandable structure is arranged in the housing corresponding to at least one of the vents. The thermal-expandable structure expands to seal the corresponding vent when being heated to greater than or equal to a predetermined temperature.

One of the exemplary embodiments, the electronic assembly has a battery cell.

One of the exemplary embodiments, a grid is arranged on the vent. The thermal-expandable structure may be attached on the grid and located at an inner side of the housing. The thermal-expandable structure expands to seal the respective holes.

One of the exemplary embodiments, a plurality of holes is defined on the grid, and the thermal-expandable structure may be disposed on a periphery of each hole. The thermal-expandable structure expands to seal each hole.

This disclosure is directed to a having a housing, an electronic assembly, and a thermal-expandable structure. The housing is provided with a pair of vents. The electronic assembly is accommodated in the housing. At least a portion of the electronic assembly is separated from the housing and a flow channel is enclosed by the electronic assembly and an internal surface of the housing, and the flow channel is extended between the pair of vents. The thermal-expandable structure is arranged in the housing corresponding to at least one of the vents. The thermal-expandable structure expands to seal the corresponding vent when being heated to greater than or equal to a predetermined temperature.

One of the exemplary embodiments, the electronic assembly includes a battery cell. The thermal-expandable structure is disposed between the housing and the electronic assembly, and the thermal-expandable structure is separated from the electronic assembly. The thermal-expandable structure expands to contact the electronic assembly. A grid is arranged on the vent.

This disclosure is directed to a flameproof electronic device having a housing, an electronic assembly, and a thermal-expandable structure. The housing is provided with a pair of vents. The electronic assembly is accommodated in the housing. At least a portion of the electronic assembly is separated from the housing and a flow channel is enclosed by the electronic assembly and an internal surface of the housing, and the flow channel is extended between the pair of vents. The thermal-expandable structure is attached on an external surface of the electronic assembly. The thermal-expandable structure expands to block at least a portion of the flow channel when being heated to a temperature greater than or equal to a predetermined temperature.

One of the exemplary embodiments, the electronic assembly includes a battery cell. The thermal-expandable structure is disposed between the vent and the electronic assembly and the thermal-expandable structure is separated from the vent. The thermal-expandable structure is disposed between the internal surface of the housing and the electronic assembly, and the thermal-expandable structure is separated from the housing. The thermal-expandable structure expands to contact the internal surface of the housing. A grid is arranged on the vent.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is an exploded view showing the flameproof electronic device according to the first embodiment of this disclosure.

FIG. 2 is a partially enlarged view of the flameproof electronic device according to the first embodiment of this disclosure.

FIGS. 3 and 4 are perspective views showing operation status of the flameproof electronic device according to the first embodiment of this disclosure.

FIGS. 5 and 6 are perspective views showing other types of the flameproof electronic device according to the first embodiment of this disclosure.

FIG. 7 is an exploded view showing the flameproof electronic device according to the second embodiment of this disclosure.

FIG. 8 is a lateral cross-sectional view of the flameproof electronic device according to the third embodiment of this disclosure.

FIGS. 9 and 10 are perspective views showing operation status of the flameproof electronic device according to the second embodiment of this disclosure.

FIG. 11 is an exploded view showing the flameproof electronic device according to the third embodiment of this disclosure.

FIG. 12 is a lateral cross-sectional view of the flameproof electronic device according to the third embodiment of this disclosure.

FIG. 13 is a perspective view showing operation status of the flameproof electronic device according to the third embodiment of this disclosure.

FIG. 14 is a perspective view showing another type of the flameproof electronic device according to the third embodiment of this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

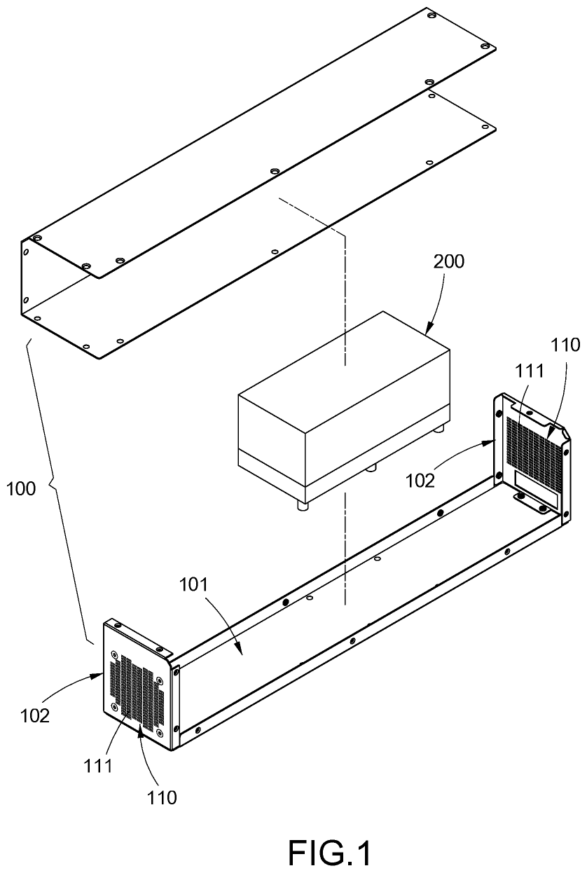

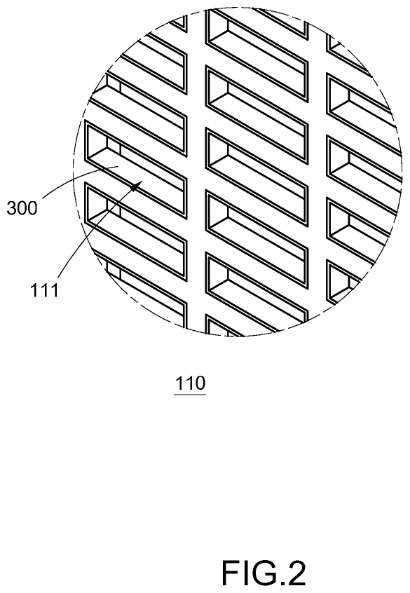

According to FIGS. 1 to 3, an embodiment of this disclosure provides a flameproof electronic device having a housing 100, an electronic assembly 200 and a thermal-expandable structure 300.

The flameproof electronic device of this disclosure is a housing structure having a battery therein. For example, the housing 100 may be a battery module housing, a server chassis, a rack, a cabinet, or a battery room of a vehicle. The housing 100 is provided with a pair of vents 102 and an accommodation space, the housing 100 is of an elongated shape according to this embodiment, and the vents 102 are respectively arranged at two ends of the housing 100. However, the housing 100 should not be limited to the shape shown in the embodiment. A grid 110 is arranged on each vent 102, and each grid 110 has a plurality of holes 111 allowing air to flow through the vent 102.

The electronic assembly 200 has at least one battery cell, the electronic assembly 200 may further have electronic elements electrically connected with the battery cell, and the electronic elements are used for controlling charging or discharging of the battery cell. According to this embodiment, the battery cell and the electronic elements of the electronic assembly 200 are arranged in an elongated arrangement suitable for being accommodated in the accommodation space of housing 100, but the electronic assembly 200 should not be limited to the shape shown in the embodiment. At least a portion of the electronic assembly 200 is separated from the housing 100 and a flow channel 101 is defined between the electronic assembly 200 and an internal surface of the housing 100 so as to allow air to flow therein for dissipating heat from the electronic assembly 200. Specifically, the flow channel 101 is extended between the pair of vents 102 along the housing 100 of the elongated shape, two ends of the flow channel 101 respectively communicate to the two vents 102, and the electronic assembly 200 is arranged in a middle segment of the flow channel 101.

The thermal-expandable structure 300 is arranged in the housing 100 corresponding to the vents 102, and the thermal-expandable structure 300 is arranged on a periphery of each hole 111. Specifically, the periphery of each hole 111 is covered or attached by a layer of thermal expansion material so as to form the thermal-expandable structure 300.

The thermal expansion material includes four main components: a catalyst is first decomposed to release an acidic substance, which is generally phosphoric acid; a carbonific agent, which is a carbohydrate such as starch, is combined with a mineral acid to be a carbonaceous char; an adhesive such as a resin is softened in a high temperature reaction; when the adhesive is softened, a spumific agent is decomposed to release a large amount of non-flammable gases such as carbon dioxide and water vapor, so that the gases make the softened adhesive foam and a thickness of the carbonaceous char is expanded to dozens of times. In this embodiment, the thermal expansion material may include a thermal expansion paint, such as Rainbow FM-900 for building, may be arranged by coating or spray coating. The thermal expansion material may be selected according to various triggering temperature and requirements of flame-resistant time. According to an example of Rainbow FM-900, a foamed layer is formed in a temperature greater than or equal to 200° C. and rapidly expands dozens of times into a thermal insulation layer as the increasing of temperature in the housing. Various flame-resistant performances of 30, 60, 90 and 120 minutes are available according to various coating thicknesses

In some embodiment of the disclosure, the thermal expansion material may be attached on a non-woven fabric or other suitable carrier to form the thermal-expandable structure 300. Then, the thermal-expandable structure 300 may be pasted on the grid or other surfaces in the housing through the non-woven fabric or carrier.

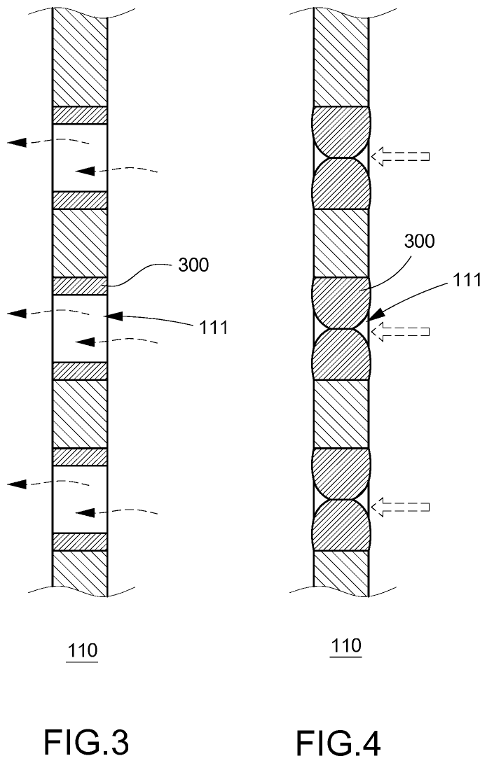

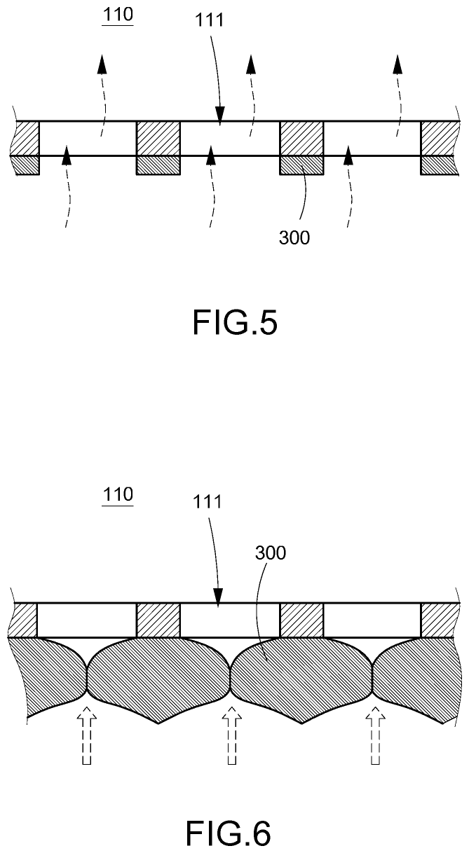

According to FIGS. 3 and 4, the thermal-expandable structure 300 may expand to seal the vent 102 when being heated to a temperature greater than or equal to a predetermined temperature. Specifically, the thermal-expandable structure 300 expands to seal each hole 111. According to FIGS. 5 and 6, the thermal-expandable structure 300 is attached on the grid 110 and located inside the housing 100, the thermal-expandable structure 300 expands to seal the vent 102 when being heated to greater than or equal to a predetermined temperature. Specifically, the thermal-expandable structure 300 expands to seal each hole 111.

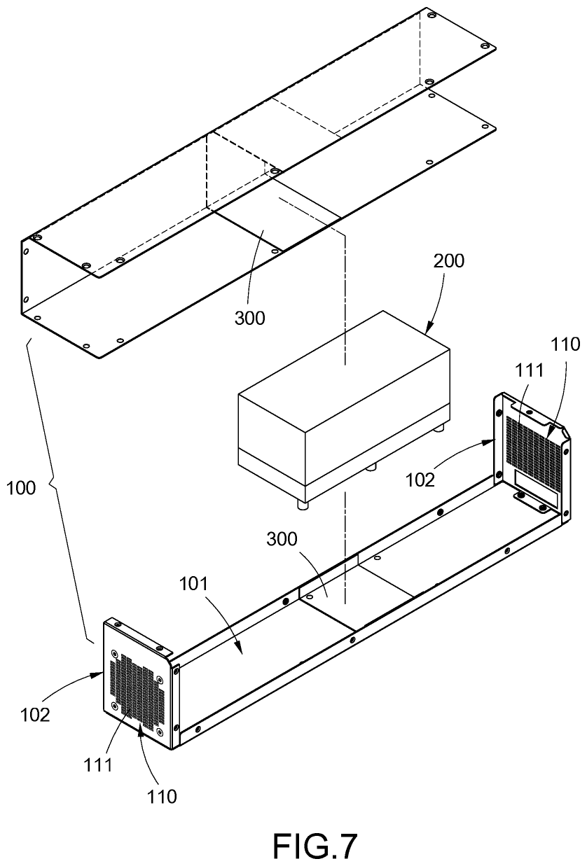

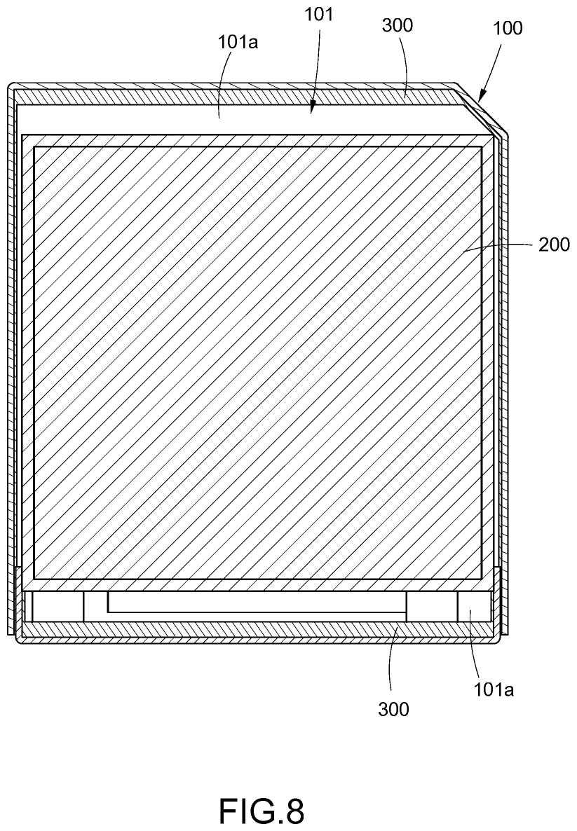

According to FIGS. 7 to 8, an embodiment of this disclosure provides a flameproof electronic device having a housing 100, an electronic assembly 200 and a thermal-expandable structure 300.

The flameproof electronic device of this disclosure is a housing structure having a battery therein. For example, the housing 100 may be a battery module housing, a server chassis, a rack, a cabinet, or a battery room of a vehicle. The housing 100 is provided with a pair of vents 102, the housing 100 is of an elongated shape according to this embodiment, and the vents 102 are respectively arranged at two ends of the housing 100. However, the housing 100 should not be limited to the shape shown in the embodiment. A grid 110 is arranged on each vent 102, and each grid 110 has a plurality of holes 111 allowing air to flow through the vent 102.

The electronic assembly 200 has at least one battery cell, the electronic assembly 200 may further have electronic elements electrically connected with the battery cell, and the electronic elements are used for controlling charging or discharging of the battery cell. According to this embodiment, the battery cell and the electronic elements of the electronic assembly 200 are arranged in an elongated arrangement suitable for being accommodated in the housing 100, but the electronic assembly 200 should not be limited to the shape shown in the embodiment. At least a portion of the electronic assembly 200 is separated from the housing 100 and a flow channel 101 is defined between the electronic assembly 200 and an internal surface of the housing 100 so as to allow air to flow therein for dissipating heat from the electronic assembly 200. Specifically, the flow channel 101 is extended between the pair of vents 102 along the housing 100 of the elongated shape, two ends of the flow channel 101 respectively communicate to the two vents 102, and the electronic assembly 200 is arranged in a middle segment of the flow channel 101.

The thermal-expandable structure 300 is attached on an internal surface of the housing 100, the thermal-expandable structure 300 in this embodiment is arranged in a middle segment of the flow channel 101 and surrounds a lateral surface of the electronic assembly 200. Specifically, a layer of thermal expansion material is covered on at least a portion of a region on the internal surface of the housing 100 adjacent to and separated from the electronic assembly 200 to form the thermal-expandable structure 300. Moreover, on at least one cross section of the housing 100, the flow channel 101 is a gap 101a between the housing 100 and the electronic assembly 200, and the thermal-expandable structure 300 is at least extended to cover the longest side of the gap 101a.

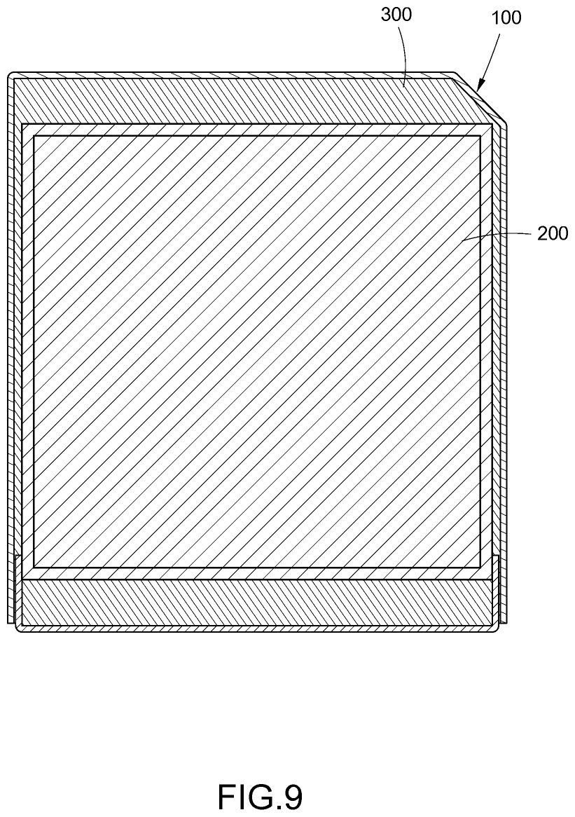

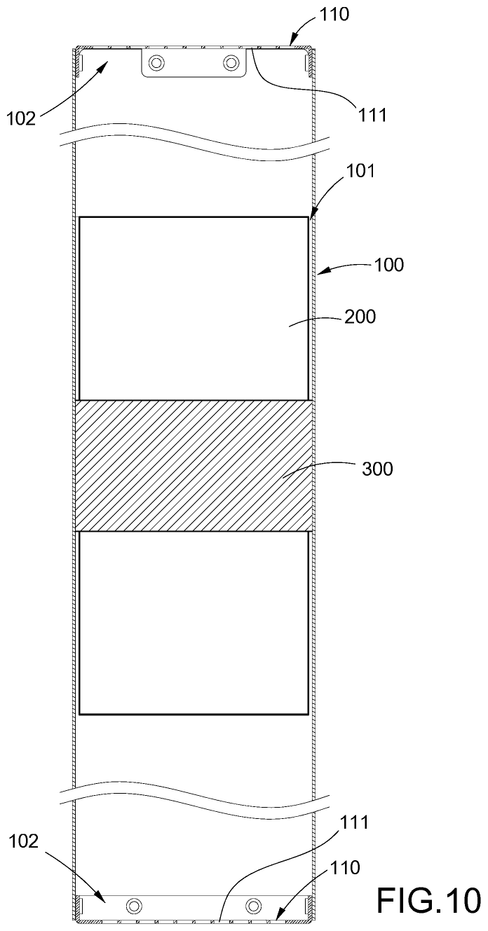

According to FIGS. 7 to 8, the thermal-expandable structure 300 is located between the housing 100 and the electronic assembly 200, and the thermal-expandable structure 300 is separated from the electronic assembly 200 to allow the air to pass therethrough. According to FIGS. 9 to 10, the thermal-expandable structure 300 expands to contact to the electronic assembly 200 and block at least a portion of the flow channel 101 namely the aforementioned gap 101a when being heated to a temperature greater than or equal to a predetermined temperature. The layer of thermal expansion material may cover all of the region on the internal surface of the housing 100 adjacent to and separated from the electronic assembly 200 so that the thermal-expandable structure 300 may further fill the middle segment of the flow channel 101 to block the flow channel 101 more effectively.

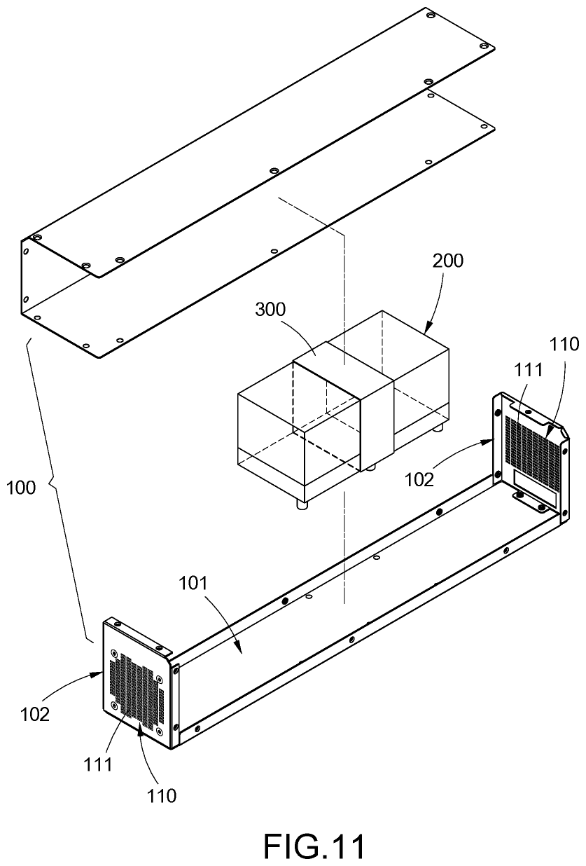

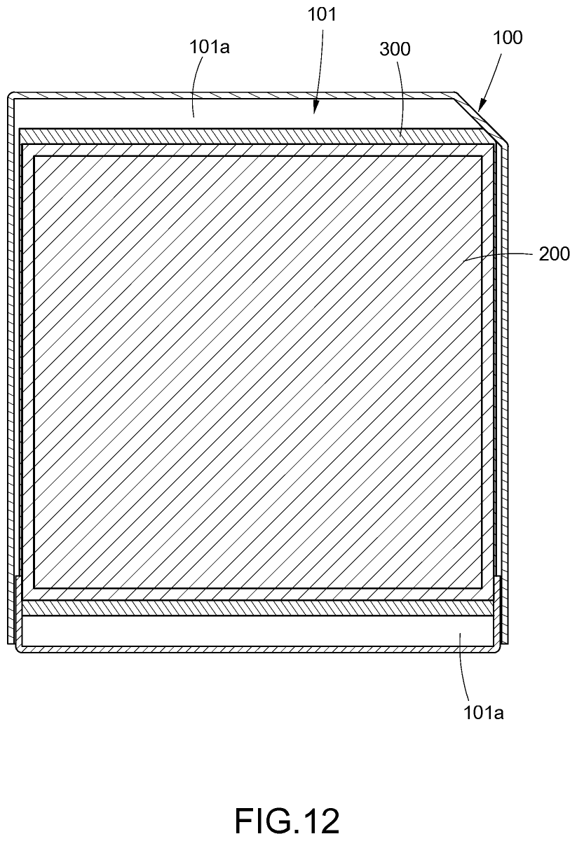

According to FIGS. 11 and 12, an embodiment of this disclosure provides a flameproof electronic device having a housing 100, an electronic assembly 200 and a thermal-expandable structure 300.

The flameproof electronic device of this disclosure is a housing structure having a battery therein. For example, the housing 100 may be a battery module housing, a server chassis, a rack, a cabinet, or a battery room of a vehicle. The housing 100 is provided with a pair of vents 102, the housing 100 is of an elongated shape according to this embodiment, and the vents 102 are respectively arranged at two ends of the housing 100. However, the housing 100 should not be limited to the shape shown in the embodiment. A grid 110 is arranged on each vent 102, and each grid 110 has a plurality of holes 111 allowing air to flow through the vent 102.

The electronic assembly 200 has at least one battery cell, the electronic assembly 200 may further have electronic elements electrically connected with the battery cell, and the electronic elements are used for controlling charging or discharging of the battery cell. According to this embodiment, the battery cell and the electronic elements of the electronic assembly 200 are arranged in an elongated arrangement suitable for being accommodated in the housing 100, but the electronic assembly 200 should not be limited to the shape shown in the embodiment. At least a portion of the electronic assembly 200 is separated from the housing 100 and a flow channel 101 is defined between the electronic assembly 200 and an internal surface of the housing 100 so as to allow air to flow therein for dissipating heat from the electronic assembly 200. Specifically, the flow channel 101 is extended between the pair of vents 102 along the housing 100 of the elongated shape, two ends of the flow channel 101 respectively communicate to the two vents 102, and the electronic assembly 200 is arranged in a middle segment of the flow channel 101.

The thermal-expandable structure 300 is attached on an external surface of the electronic assembly 200, the thermal-expandable structure 300 according to this embodiment is arranged in a middle segment of the flow channel 101 and the thermal-expandable structure 300 surrounds a lateral surface of the electronic assembly 200. Specifically, at least a portion of a region on the electronic assembly 200 adjacent to and separated from the internal surface of the housing 100 is covered by a layer of thermal expansion material so as to form the thermal-expandable structure 300. Moreover, on at least one cross section of the housing 100, the flow channel 101 is a gap 101a between the housing 100 and the electronic assembly 200, and the thermal-expandable structure 300 is extended to fully cover a length of the gap 101a.

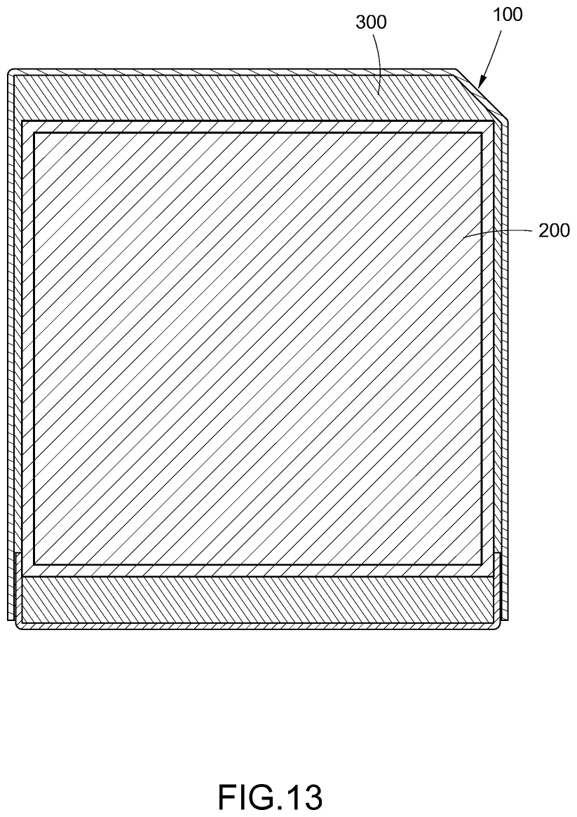

According to FIGS. 11 to 12, the thermal-expandable structure 300 is located between the housing 100 and the electronic assembly 200, and the thermal-expandable structure 300 is separated from the electronic assembly 200 to allow the air to pass therethrough. According to FIG. 13, the thermal-expandable structure 300 expands to contact to the internal surface of the housing 100 when being heated to a temperature greater than or equal to a predetermined temperature to block at least a portion of the flow channel 101 namely the aforementioned gap 101a. The layer of thermal expansion material may cover all of the lateral surface of the electronic assembly 200 so that the thermal-expandable structure 300 may further fill the middle segment of the flow channel 101 to block the flow channel 101 more effectively.

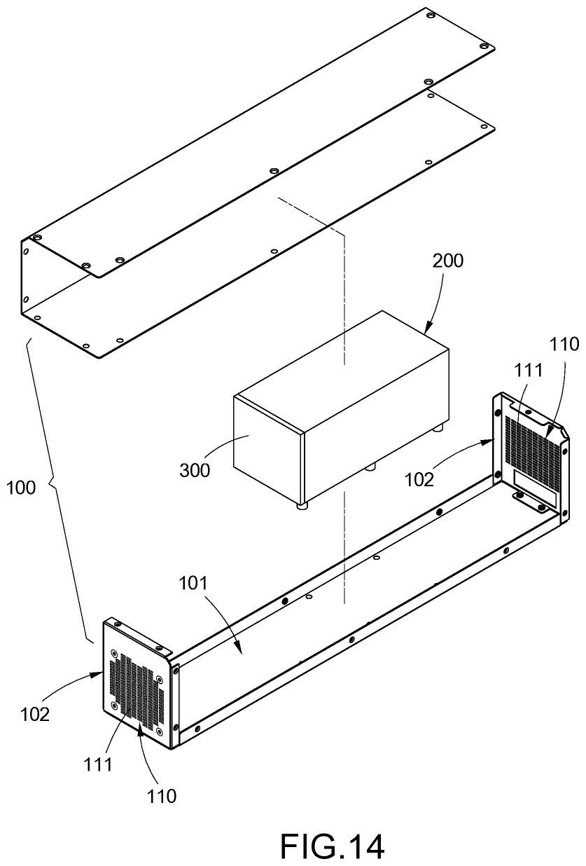

According to FIG. 14, the thermal-expandable structure 300 may be covered or attached on an end surface of an end of the electronic assembly 200 so as to form the thermal-expandable structure 300, the thermal-expandable structure 300 is located between the vent 102 and the electronic assembly 200, and the thermal-expandable structure 300 is separated from the vent 102 to allow the air to pass therethrough. The thermal-expandable structure 300 expands when being heated to a temperature greater than or equal to a predetermined temperature so that a periphery of the thermal-expandable structure 300 contacts the internal surface of the housing 100 to block at least a portion of the flow channel 101. According to this embodiment, end surfaces of two end of the electronic assembly 200 may be respectively covered by layer of thermal expansion material, so that the thermal-expandable structure 300 may seal two ends of the flow channel 101 to block flow channel 101 more effectively.

According to this disclosure, the layer of thermal expansion material covers the internal surface of the housing 100 (a periphery of the hole 111 of the housing 100 is a part of this internal surface) or covers the external surface of the electronic assembly 200 so as to form the thermal-expandable structure 300. Once the electronic assembly 200 catches fire, the thermal-expandable structure 300 is heated and expands to form a wall at a position in the flow channel 101 to extinguish the flame in the housing 100.

This wall may also suppress an air convection in the housing 100 to reduce an amount of outside combustion-supporting gas (such as oxygen in the atmosphere) entering into the housing 100, thereby suppressing flame generation in the housing 100.

Accordingly, this disclosure may be applied to achieve the predetermined purpose so as to solve the problems of the related art. While this disclosure has been described by means of specific embodiments, numerous modifications and variations could be made thereto by those skilled in the art without departing from the scope and spirit of this disclosure set forth in the claims.

What is claimed is:

1. A flameproof electronic device, comprising:
a housing, having an accommodation space and a pair of vents;
an electronic assembly, disposed in the accommodation space of the housing, wherein at least a portion of the electronic assembly is separated from the housing and a flow channel is enclosed by the electronic assembly and an internal surface of the housing, and the flow channel is extended between the pair of vents; and
a thermal-expandable structure, arranged in the accommodation space of the housing and corresponding to at least one of the vents,
wherein the thermal-expandable structure is configured to expand to seal the vent correspondingly when the thermal-expandable structure is heated to greater than or equal to a predetermined temperature.

2. The flameproof electronic device according to claim 1, wherein the electronic assembly comprises a battery cell.

3. The flameproof electronic device according to claim 1, wherein a grid is arranged on the vent and the thermal-expandable structure is attached on the grid and located at an inner side of the housing.

4. The flameproof electronic device according to claim 3, wherein a plurality of holes is defined on the grid, and the thermal-expandable structure is formed by coating or spray coating a layer of thermal expansion material on a periphery of each hole.

5. The flameproof electronic device according to claim 3, wherein a plurality of holes is defined on the grid, and the thermal-expandable structure is formed by attaching a layer of thermal expansion material on a non-woven fabric and then pasting on a periphery of each hole.

6. The flameproof electronic device according to claim 4, wherein the thermal-expandable structure is configured to expand to seal the plurality of holes.

7. The flameproof electronic device according to claim 5, wherein the thermal-expandable structure is configured to expand to seal the plurality of holes

8. A flameproof electronic device, comprising:
a housing, having an accommodation space and a pair of vents;
an electronic assembly, disposed in the accommodation space of the housing, wherein at least a portion of the electronic assembly is separated from the housing and a flow channel is enclosed by the electronic assembly and an internal surface of the housing, and the flow channel is extended between the pair of vents;
a thermal-expandable structure, attached on the internal surface of the housing,
wherein the thermal-expandable structure is configured to expand to block at least a portion of the flow channel when the thermal-expandable structure is heated to greater than or equal to a predetermined temperature.

9. The flameproof electronic device according to claim 8, wherein the electronic assembly comprises a battery cell.

10. The flameproof electronic device according to claim 8, wherein the thermal-expandable structure is disposed between the housing and the electronic assembly, and the thermal-expandable structure is separated from the electronic assembly.

11. The flameproof electronic device according to claim 10, wherein the thermal-expandable structure is configured to expand to contact the electronic assembly.

12. The flameproof electronic device according to claim 8, wherein the thermal-expandable structure is formed by coating or spray coating a layer of thermal expansion material on the internal surface of the housing.

13. The flameproof electronic device according to claim 8, wherein the thermal-expandable structure is formed by attaching a layer of thermal expansion material on a non-woven fabric and then pasting on the internal surface of the housing.

14. A flameproof electronic device, comprising:
a housing, having an accommodation space and a pair of vents;
an electronic assembly, disposed in the accommodation space of the housing, wherein at least a portion of the electronic assembly is separated from the housing and a flow channel is enclosed by the electronic assembly and an internal surface of the housing, and the flow channel is communicated with the pair of vents;
a thermal-expandable structure, attached on an external surface of the electronic assembly,
wherein the thermal-expandable structure is configured to expand to block at least a portion of the flow channel when the thermal-expandable structure is heated to greater than or equal to a predetermined temperature.

15. The flameproof electronic device according to claim 14, wherein the electronic assembly comprises a battery cell.

16. The flameproof electronic device according to claim 14, wherein the thermal-expandable structure is disposed between the vent and the electronic assembly and the thermal-expandable structure is separated from the vent.

17. The flameproof electronic device according to claim 14, wherein the thermal-expandable structure is disposed between the internal surface of the housing and the electronic assembly, and the thermal-expandable structure is separated from the housing.

18. The flameproof electronic device according to claim 14, wherein the thermal-expandable structure is configured to expand to contact the internal surface of the housing.

19. The flameproof electronic device according to claim 14, wherein the thermal-expandable structure is formed by coating or spray coating a layer of thermal expansion material on the external surface of the electronic assembly.

20. The flameproof electronic device according to claim 14, wherein thermal-expandable structure is formed by attaching a layer of thermal expansion material on a non-woven fabric and then pasting on the external surface of the electronic assembly.
